(19) United States
(12) Patent Application Publication
(10) Pub. No.: US 2024/0296980 A1
(43) Pub. Date: Sep. 5, 2024

(54) SEMICONDUCTOR DEVICE

(71) Applicant: ROHM CO., LTD., Kyoto-shi (JP)

(72) Inventors: Keiji WADA, Kyoto-shi (JP); Kazumasa NISHIO, Kyoto-shi (JP)

(21) Appl. No.: 18/658,632

(22) Filed: May 8, 2024

Related U.S. Application Data
(63) Continuation of application No. PCT/JP2022/038987, filed on Oct. 19, 2022.

(30) Foreign Application Priority Data
Nov. 12, 2021 (JP) 2021-184533

(51) Int. Cl. H01C 13/02; H01L 23/00; H01L 25/18; H01L 27/08

(52) U.S. Cl. CPC H01C 13/02; H01L 24/48; H01L 25/18; H01L 27/0802; H01L 2224/48106; H01L 2924/19043

(57) ABSTRACT

A first resistor circuit includes a plurality of first resistors that extend in a first direction and are disposed at intervals in a second direction orthogonal to the first direction in plan view, a second resistor circuit includes one second resistor that extends in the first direction or a plurality of second resistors that extend in the first direction and are disposed at intervals in the second direction, a third resistor circuit includes one third resistor that extends in the first direction or a plurality of third resistors that extend in the first direction and are disposed at intervals in the second direction, a fourth resistor circuit includes a plurality of fourth resistors that extend in the first direction and are disposed at intervals in the second direction, the second resistors include one or a plurality of intermediate second resistors disposed between two first resistors adjacent in the second direction among the plurality of first resistors, and the third resistors include one or a plurality of intermediate third resistors disposed between two fourth resistors adjacent in the second direction among the plurality of fourth resistors.

### CROSS REFERENCE TO RELATED APPLICATIONS

The present application is a continuation application of PCT Application No. PCT/JP2022/038987, filed on Oct. 19, 2022, which corresponds to Japanese Patent Application No. 2021-184533 filed on Nov. 12, 2021 with the Japan Patent Office, and the entire disclosure of this application is incorporated herein by reference.

### TECHNICAL FIELD

The present disclosure relates to a semiconductor device.

### BACKGROUND ART

As a vehicle driving battery installed in a hybrid vehicle or an electric automobile, that which is high in output voltage is used. Also, the output voltage of the vehicle driving battery is boosted and supplied to a motor drive circuit. Such a vehicle is thus provided with a voltage monitoring device (high voltage monitor) arranged to monitor the high voltage supplied to the motor drive circuit.

A voltage monitoring device constituted of a first chip that drops a signal of high voltage and a second chip that signal processes the signal dropped by the first chip is disclosed in Japanese Patent Application Publication No. 2016-136608 mentioned below. In Japanese Patent Application Publication No. 2016-136608, although a circuit diagram of a resistor circuit of the first chip is disclosed, a specific configuration of a plurality of resistor elements inside the first chip is not disclosed.

Also, in Japanese Patent Application Publication No. 2017-79254 mentioned below, a structure of a single resistor element inside a first chip is disclosed, a specific configuration of a plurality of resistor elements inside the first chip is not disclosed.

### BRIEF DESCRIPTION OF DRAWINGS

FIG. 1 is an illustrative plan view showing a semiconductor device according to a preferred embodiment of the present invention.

FIG. 2 is a schematic view mainly showing the general electrical arrangement of a first chip and the general electrical arrangement of a second chip.

FIG. 3 is an illustrative plan view of the first chip.

FIG. 4 is a sectional view taken along line IV-IV of FIG. 3.

FIG. 5 is a sectional view showing a connection structure of resistors in FIG. 4.

FIG. 6 is an illustrative plan view for describing a comparative example of the first chip.

FIG. 7 is a partial plan view showing a modification example of dummy resistors that are disposed between a second resistor circuit and real resistors adjacent thereto of a first resistor circuit.

FIG. 8 is an illustrative plan view for describing a modification example of the first chip.

### DESCRIPTION OF EMBODIMENTS

A preferred embodiment of the present disclosure provides a semiconductor device including a first resistor circuit that is electrically connected to a positive electrode of a high voltage generating portion, a second resistor circuit that is connected in series to the first resistor circuit, a third resistor circuit that is connected in series to the second resistor circuit, and a fourth resistor circuit that is connected in series to the third resistor circuit and electrically connected to a negative electrode of the high voltage generating portion and where the first resistor circuit includes a plurality of first resistors that extend in a first direction and are disposed at intervals in a second direction orthogonal to the first direction in plan view, the second resistor circuit includes one second resistor that extends in the first direction or a plurality of second resistors that extend in the first direction and are disposed at intervals in the second direction, the third resistor circuit includes one third resistor that extends in the first direction or a plurality of third resistors that extend in the first direction and are disposed at intervals in the second direction, the fourth resistor circuit includes a plurality of fourth resistors that extend in the first direction and are disposed at intervals in the second direction, the second resistors include one or a plurality of intermediate second resistors disposed between two first resistors adjacent in the second direction among the plurality of first resistors, and the third resistors include one or a plurality of intermediate third resistors disposed between two fourth resistors adjacent in the second direction among the plurality of fourth resistors.

With this arrangement, it is made possible to reduce a voltage detection error that is based on process variation.

In the preferred embodiment of the present disclosure, resistance values of the first resistors, the second resistors, the third resistors, and the fourth resistors are equal.

In the preferred embodiment of the present disclosure, a ratio of a resistance value of the second resistor circuit with respect to a resistance value of the first resistor circuit is equal to a ratio of a resistance value of the third resistor circuit with respect to a resistance value of the fourth resistor circuit.

In the preferred embodiment of the present disclosure, one or a plurality of first dummy resistors are disposed between the two first resistors between which the one or plurality of intermediate second resistors are disposed and the intermediate second resistors and one or a plurality of second dummy resistors are disposed between the two fourth resistors between which the one or plurality of intermediate third resistors are disposed and the intermediate third resistors.

In the preferred embodiment of the present disclosure, resistance values of the first resistors, the second resistors, the third resistors, the fourth resistors, the first dummy resistors, and the second dummy resistors are equal.

In the preferred embodiment of the present disclosure, the first resistor circuit includes a predetermined number of two or more of columns each constituted of a plurality of the first resistors that extend in the first direction and are disposed at intervals in the second direction, the fourth resistor circuit includes a predetermined number of two or more of columns each constituted of a plurality of the fourth resistors that extend in the first direction and are disposed at intervals in the second direction, the second resistor circuit includes one or a plurality of second resistors disposed in correspondence to each column of the first resistors, and the third resistor circuit includes one or a plurality of third resistors disposed in correspondence to each column of the fourth resistors.

In the preferred embodiment of the present disclosure, all of the first resistors constituting the first resistor circuit are connected in series and all of the fourth resistors constituting the fourth resistor circuit are connected in series.

In the preferred embodiment of the present disclosure, the second resistor circuit includes at least four or more second resistors, the third resistor circuit includes at least four or more third resistors, the second resistor circuit includes a plurality of first parallel circuits each constituted of two or more of the second resistors being connected in parallel, the third resistor circuit includes a plurality of second parallel circuits each constituted of two or more of the third resistors being connected in parallel, the plurality of first parallel circuits are connected in series, and the plurality of second parallel circuits are connected in series.

In the preferred embodiment of the present disclosure, a voltage detecting portion arranged to measure a voltage that is in accordance with a voltage between a connection point of the first resistor circuit and the second resistor circuit and a connection point of the third resistor circuit and the fourth resistor circuit is included.

In the following, preferred embodiments of the present disclosure shall be described in detail with reference to the accompanying drawings.

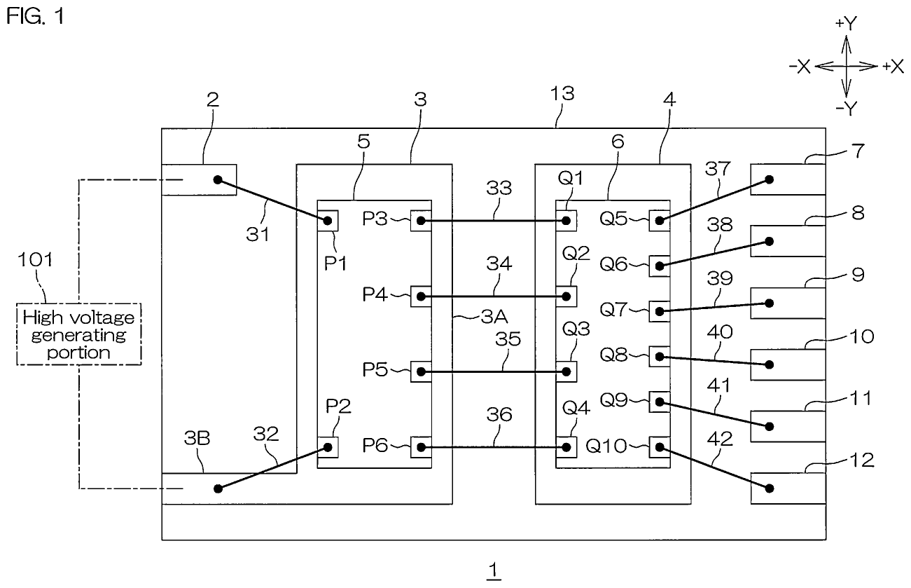

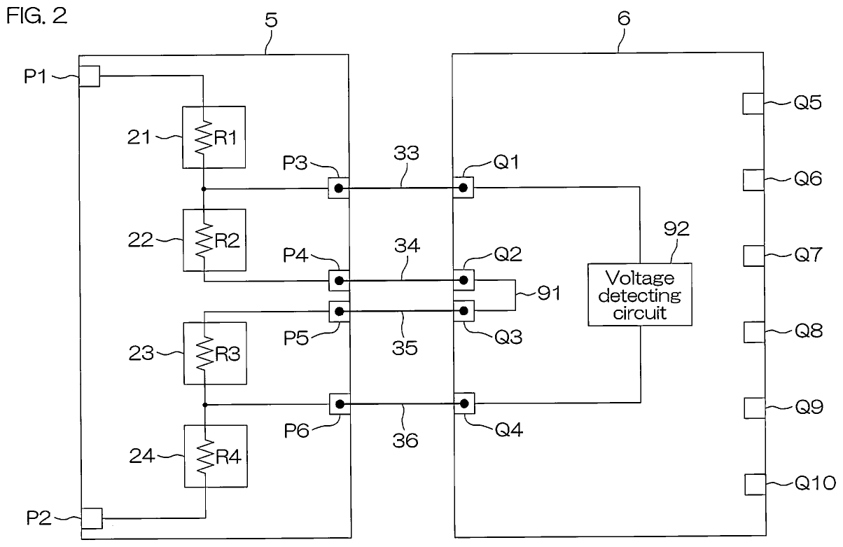

FIG. 1 is an illustrative plan view showing a semiconductor device according to a preferred embodiment of the present invention. FIG. 2 is a schematic view mainly showing the general electrical arrangement of a first chip and the general electrical arrangement of a second chip.

For convenience of description, a +X direction, a −X direction, a +Y direction, and a −Y direction shown in FIG. 1 are used at times in the following description. The +X direction is a predetermined direction along a front surface of a semiconductor device 1 in plan view and the +Y direction is a direction along the front surface of the semiconductor device 1 in plan view and is a direction that is orthogonal to the +X direction. The −X direction is a direction opposite to the +X direction and the −Y direction is a direction opposite to the +Y direction. The +X direction and the −X direction shall be referred to simply as the “X direction” when referred to collectively. The +Y direction and the −Y direction shall be referred to simply as the “Y direction” when referred to collectively.

The semiconductor device 1 includes a first lead 2, a first frame 3, a second frame 4, a first chip 5 that is fixed on the first frame 3, a second chip 6 that is fixed on the second frame 4, second to seventh leads 7 to 12 that are connected to the second chip 6, wirings 31 to 42, and a sealing resin 13 that seals the above.

In plan view, the first frame 3 includes a main body portion 3A of a rectangular shape that is long in the Y direction and a lead portion 3B that extends in the −X direction from a −Y side end portion of a −X side edge of the main body portion 3A. The first lead 2 is disposed at an interval to a −X side with respect to a +Y side end portion of the −X side edge of the main body portion 3A of the first frame 3.

In plan view, the second frame 4 is disposed at an interval to a +X side with respect to the main body portion 3A of the first frame 3. The second frame 4 has a rectangular shape that is long in the Y direction in plan view. In plan view, the second to seventh leads 7 to 12 are disposed at an interval to the +X side with respect to the second frame 4. In plan view, the second to seventh leads 7 to 12 are disposed at an intervals in the Y direction.

With each of the first lead 2, the lead portion 3B, and the second to seventh leads 7 to 12, a portion (for example, a lower surface and an outer end surface) is exposed from the sealing resin 13.

The first chip 5 includes a plurality of terminals P1 to P6. The terminal P1 is connected to the first lead 2 via the wiring 31. The terminal P2 is connected to the lead portion 3B via the wiring 32. A positive electrode of a high voltage generating portion 101 is connected to the first lead 2. A negative electrode of the high voltage generating portion 101 is connected to the lead portion 3B.

As shown in FIG. 2, the first chip 5 includes first to fourth resistor circuits 21 to 24 arranged to drop a high voltage of the high voltage generating portion 101 (see FIG. 1). The first to fourth resistor circuits 21 to 24 are connected in series.

One end of the first resistor circuit 21 is connected to the terminal P1. Another end of the first resistor circuit 21 is connected to one end of the second resistor circuit 22. A connection point of the first resistor circuit 21 and the second resistor circuit 22 is connected to the terminal P3. Another end of the second resistor circuit 22 is connected to the terminal P4. One end of the third resistor circuit 23 is connected to the terminal P5. Another end of the third resistor circuit 23 is connected to one end of the fourth resistor circuit 24. A connection point of the third resistor circuit 23 and the fourth resistor circuit 24 is connected to the terminal P6. Another end of the fourth resistor circuit 24 is connected to the terminal P2.

As shall be described below, the terminal P4 and the terminal P5 are connected to each other by a wiring passing through the second chip 6. That is, the other end of the second resistor circuit 22 and the one end of the third resistor circuit 23 are electrically connected.

In the following, a resistance value of the first resistor circuit 21 shall be R1, a resistance value of the second resistor circuit 22 shall be R2, a resistance value of the third resistor circuit 23 shall be R3, and a resistance value of the fourth resistor circuit 24 shall be R4.

R2 is less than R1 and a ratio (R2/R1) of R2 with respect to R1 is set in advance. R3 is less than R4 and a ratio (R3/R4) of R3 with respect to R4 is set in advance. The ratio (R2/R1) and the ratio (R3/R4) are set to the same predetermined value (for example, 1/999).

The second chip 6 includes a plurality of terminals Q1 to Q10. The terminals Q1 to Q4 are connected to the terminal P3 to the terminal P6 via the wirings 33 to 36, respectively. The terminals Q5 to Q10 are connected to the second to seventh leads 7 to 12 via the wirings 37 to 42, respectively. As shown in FIG. 2, the terminal Q2 and the terminal Q3 are connected by a wiring 91 inside the second chip 6.

The second chip 6 includes a voltage detecting circuit 92 that is connected between the terminal Q1 and the terminal Q4. The voltage detecting circuit 92 detects a voltage that is in accordance with a voltage between a connection point of the first resistor circuit 21 and the second resistor circuit 22 and a connection point of the third resistor circuit 23 and the fourth resistor circuit 24. The voltage detecting circuit 92 includes an operational amplifier. The terminals Q5 to Q10 (second to seventh leads 7 to 12) are used to supply a power supply voltage to the operational amplifier inside the second chip 6 and output an output signal of the voltage detecting circuit 92.

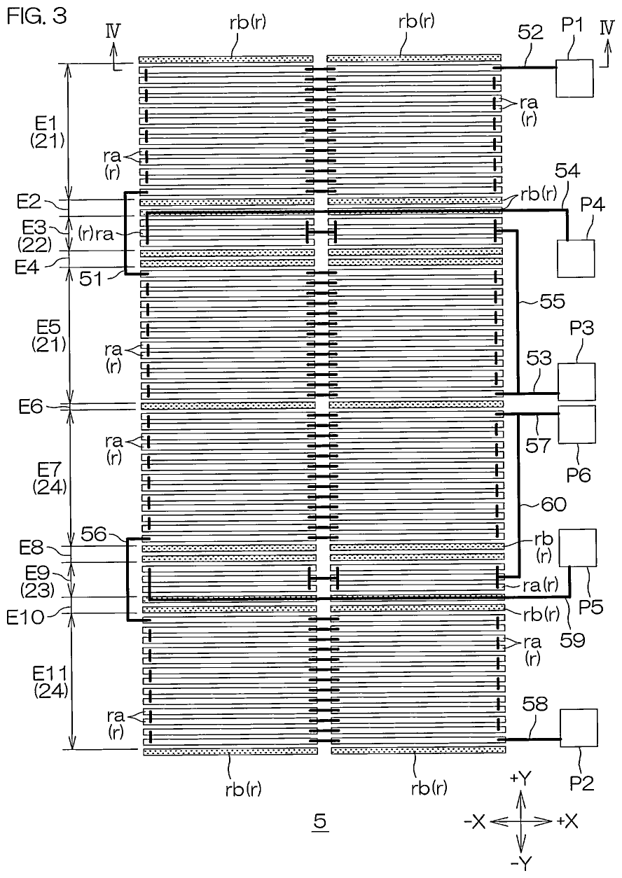

FIG. 3 is an illustrative plan view of the first chip 5.

Two columns each constituted of a plurality of unit resistors r (hereinafter referred to as the “resistors r”) that extend in the X direction and are disposed at intervals in the Y direction are provided at an interval in the X direction in plan view in the first chip 5. The plurality of resistors r include real resistors ra that are used as constituent elements of any of the resistor circuits 21 to 24 and dummy resistors rb that are not used as constituent elements of any of the resistor circuits 21 to 24. In FIG. 3, dot hatching is applied to the dummy resistors rb for clarification.

In the following, of the two resistor columns, the column at the −X side shall be referred to as the first column and the column at the +X side shall be referred to as the second column.

In this preferred embodiment, the plurality of resistors r inside the first column and the plurality of resistors r inside the second column are respectively disposed at a predetermined pitch interval in the Y direction.

In this preferred embodiment, a pair of resistors r that are at the most +Y side and are adjacent in the X direction are dummy resistors rb (referred to hereinafter as the “+Y side dummy resistors rb”). A pair of resistors r that are at the most −Y side and are adjacent in the X direction are dummy resistors rb (referred to hereinafter as the “−Y side dummy resistors rb”).

A region between the +Y side dummy resistors rb and the −Y side dummy resistors rb is divided in the Y direction into eleven regions E1 to E11 to form the first to fourth resistor circuits 21 to 24, etc. The regions E1 to E11 include regions of the same size and regions differing in size.

The regions E1 to E11 shall be referred to respectively as the first region E1, the second region E2, . . . , the tenth region E10, and the eleventh region E11 from the +Y direction side. In this preferred embodiment, the sixth region E6 is disposed at a Y-direction center of the region between the +Y side dummy resistors rb and the −Y side dummy resistors rb.

Sizes of the first region E1, the fifth region E5, the seventh region E7, and the eleventh region E11 are substantially equal and larger than those of the other regions E2, E3, E4, E8, E9, and E10. The sizes of the third region E3 and the ninth region E9 are substantially equal. The respective sizes of the second region E2, the fourth region E4, the eighth region E8, and the tenth region E10 are substantially equal. The sixth region E6 is the smallest among the first to eleventh regions E1 to E11.

The plurality of resistors r included in each of the first region E1, the third region E3, the fifth region E5, the seventh region E7, the ninth region E9, and the eleventh region E11 are real resistors ra. The plurality of resistors r included in each of the second region E2, the fourth region E4, the sixth region E6, the eighth region E8, and the tenth region E10 are dummy resistors rb.

The first resistor circuit 21 includes the plurality of real resistors ra inside the first region E1 and the plurality of real resistors ra inside the fifth region E5. The first resistor circuit 21 is constituted of a series circuit of all the real resistors ra inside the regions E1 and E5.

Specifically, inside the region E1, two real resistors ra that are adjacent in the X direction have inner end portions thereof electrically connected to each other. In the first column inside the region E1, −X side end portions of the real resistors ra of odd number rows (odd numbers) from a +Y side end are respectively connected to-X side end portions of the real resistors ra of even number rows (even numbers) that are adjacent to −Y sides thereof. In the second column inside the region E1, +X side end portions of the real resistors ra of even number rows from a +Y side end are respectively connected to +X side end portions of the real resistors ra of odd number rows that are adjacent to −Y sides thereof.

In the region E5, two real resistors ra that are adjacent in the X direction have inner end portions thereof electrically connected to each other. In the first column inside the region E5, −X side end portions of the real resistors ra of even number rows from a +Y side end are respectively connected to −X side end portions of the real resistors ra of odd number rows that are adjacent to −Y sides thereof. In the second column inside the region E5, +X side end portions of the real resistors ra of odd number rows from a +Y side end are respectively connected to +X side end portions of the real resistors ra of even number rows that are adjacent to −Y sides thereof.

A −X side end portion of the real resistor ra at a −Y side end of the first column inside the region E1 is electrically connected via a wiring 51 to a −X side end portion of the real resistor ra at the +Y side end of the first column inside the region E5. Thereby, all of the real resistors ra inside the regions E1 and E5 are connected in series. A +X side end portion of the real resistor ra at the +Y side end of the second column inside the region E1 is connected via a wiring 52 to the terminal P1. A +X side end portion of the real resistor ra at a −Y side end of the second column inside the region E5 is connected via a wiring 53 to the terminal P3.

The second resistor circuit 22 includes a plurality of real resistors ra inside the third region E3. The second resistor circuit 22 is constituted of a series circuit of a parallel circuit of a plurality (three in the example of FIG. 3) of the real resistors ra of the first column inside the third region E3 and a parallel circuit of a plurality (three in the example of FIG. 3) of the real resistors ra of the second column inside the third region E3.

Specifically, −X side end portions of the plurality of real resistors ra of the first column inside the third region E3 are electrically connected to each other and +X side end portions of these real resistors ra are electrically connected to each other. −X side end portions of the plurality of real resistors ra of the second column inside the third region E3 are electrically connected to each other and +X side end portions of these real resistors ra are electrically connected to each other.

The +X side end portions of the plurality of real resistors ra of the first column inside the third region E3 are electrically connected to the −X side end portions of the plurality of real resistors ra of the second column inside the third region E3. The −X side end portions of the plurality of real resistors ra of the first column inside the third region E3 are connected via a wiring 54 to the terminal P4. The +X side end portions of the plurality of real resistors ra of the second column inside the third region E3 are connected via a wiring 55 to the terminal P3.

The plurality of real resistors ra of the first column inside the second resistor circuit 22 are disposed between the real resistor ra at the −Y side end of the first column inside the first region E1 and the real resistor ra at the +Y side end of the first column inside the fifth region E5. That is, the plurality of real resistors ra of the first column inside the second resistor circuit 22 are disposed between the two real resistors ra adjacent in the Y direction among the plurality of real resistors ra of the first column in the first resistor circuit 21.

The plurality of real resistors ra of the second column inside the second resistor circuit 22 are disposed between the real resistor ra at the −Y side end of the second column inside the first region E1 and the real resistor ra at the +Y side end of the second column inside the fifth region E5. That is, the plurality of real resistors ra of the second column inside the second resistor circuit 22 are disposed between the two real resistors ra adjacent in the Y direction among the plurality of real resistors ra of the second column in the first resistor circuit 21. Each of the real resistors ra included in the second resistor circuit 22 is an example of an “intermediate second resistor” of the present disclosure.

The fourth resistor circuit 24 includes the plurality of real resistors ra inside the seventh region E7 and the plurality of real resistors ra inside the eleventh region E11. The fourth resistor circuit 24 is constituted of a series circuit of all the real resistors ra inside the regions E7 and E11.

Specifically, inside the region E7, two real resistors ra that are adjacent in the X direction have inner end portions thereof electrically connected to each other. In the first column inside the region E7, −X side end portions of the real resistors ra of odd number rows from a +Y side end are respectively connected to −X side end portions of the real resistors ra of even number rows that are adjacent to −Y sides thereof. In the second column inside the region E7, +X side end portions of the real resistors ra of even number rows from a +Y side end are respectively connected to +X side end portions of the real resistors ra of odd number rows that are adjacent to −Y sides thereof.

In the region E11, two real resistors ra that are adjacent in the X direction have inner end portions thereof electrically connected to each other. In the first column inside the region E11, −X side end portions of the real resistors ra of even number rows from a +Y side end are respectively connected to −X side end portions of the real resistors ra of odd number rows that are adjacent to −Y sides thereof. In the second column inside the region E11, +X side end portions of the real resistors ra of odd number rows from a +Y side end are respectively connected to +X side end portions of the real resistors ra of even number rows that are adjacent to −Y sides thereof.

A −X side end portion of the real resistor ra at a −Y side end of the first column inside the region E7 is electrically connected via a wiring 56 to a −X side end portion of the real resistor ra at the +Y side end of the first column inside the region E11. Thereby, all of the real resistors ra inside the regions E7 and E11 are connected in series. A +X side end portion of the real resistor ra at the +Y side end of the second column inside the region E7 is connected via a wiring 57 to the terminal P6. A +X side end portion of the real resistor ra at a −Y side end of the second column inside the region E11 is connected via a wiring 58 to the terminal P2.

The third resistor circuit 23 includes a plurality of real resistors ra inside the ninth region E9. The third resistor circuit 23 is constituted of a series circuit of a parallel circuit of a plurality (three in the example of FIG. 3) of the real resistors ra of the first column inside the ninth region E9 and a parallel circuit of a plurality (three in the example of FIG. 3) of the real resistors ra of the second column inside the ninth region E9.

Specifically, −X side end portions of the plurality of real resistors ra of the first column inside the ninth region E9 are electrically connected to each other and +X side end portions of these real resistors ra are electrically connected to each other. −X side end portions of the plurality of real resistors ra of the second column inside the ninth region E9 are electrically connected to each other and +X side end portions of these real resistors ra are electrically connected to each other.

The +X side end portions of the plurality of real resistors ra of the first column inside the ninth region E9 are electrically connected to the −X side end portions of the plurality of real resistors ra of the second column inside the ninth region E9. The −X side end portions of the plurality of real resistors ra of the first column inside the ninth region E9 are connected via a wiring 59 to the terminal P5. The +X side end portions of the plurality of real resistors ra of the second column inside the ninth region E9 are connected via a wiring 60 to the terminal P6.

The plurality of real resistors ra of the first column inside the third resistor circuit 23 are disposed between the real resistor ra at the −Y side end of the first column inside the seventh region E7 and the real resistor ra at the +Y side end of the first column inside the eleventh region E11. That is, the plurality of real resistors ra of the first column inside the third resistor circuit 23 are disposed between the two real resistors ra adjacent in the Y direction among the plurality of real resistors ra of the first column in the fourth resistor circuit 24.

The plurality of real resistors ra of the second column inside the third resistor circuit 23 are disposed between the real resistor ra at the −Y side end of the second column inside the seventh region E7 and the real resistor ra at the +Y side end of the second column inside the eleventh region E11. That is, the plurality of real resistors ra of the second column inside the third resistor circuit 23 are disposed between the two real resistors ra adjacent in the Y direction among the plurality of real resistors ra of the second column in the fourth resistor circuit 24. Each of the real resistors ra included in the third resistor circuit 23 is an example of an “intermediate third resistor” of the present disclosure.

In this preferred embodiment, the plurality of real resistors ra that constitute the second resistor circuit 22 are disposed between the real resistors ra adjacent in the Y direction among the plurality of real resistors ra constituting the first resistor circuit 21 and therefore, a high voltage difference is generated between the second resistor circuit 22 and the real resistors ra adjacent thereto of the first resistor circuit 21.

Also, the plurality of real resistors ra that constitute the third resistor circuit 23 are disposed between the real resistors ra adjacent in the Y direction among the plurality of real resistors ra constituting the fourth resistor circuit 24 and therefore, a high voltage difference is generated between the third resistor circuit 23 and the real resistors ra adjacent thereto of the fourth resistor circuit 24.

Thus, in this preferred embodiment, in order to relax electric fields at locations at which the high voltage differences are generated, arrangements are made to dispose dummy resistors rb at the locations at which the high voltage differences are generated.

Specifically, a plurality of the dummy resistors rb are disposed in each of the second region E2, the fourth region E4, the eighth region E8, and the tenth region E10. The respective regions E2, E4, E8, and E10 shall be referred to collectively as withstand voltage dummy arrangement regions E_{dummy}.

Two dummy resistors rb are disposed at the pitch interval in the Y direction in each of the first column and the second column of each withstand voltage dummy arrangement region E_{dummy}. That is, four dummy resistors rb disposed in two columns and two rows are disposed in the withstand voltage dummy arrangement region E_{dummy}. Each dummy resistor rb is not electrically connected to the other dummy resistors rb. Also, each dummy resistor rb is not electrically connected to any of the real resistors ra and is not electrically connected to any of the terminals P1 to P6.

In addition, one dummy resistor rb is disposed in each of the first column and the second column of the sixth region E6.

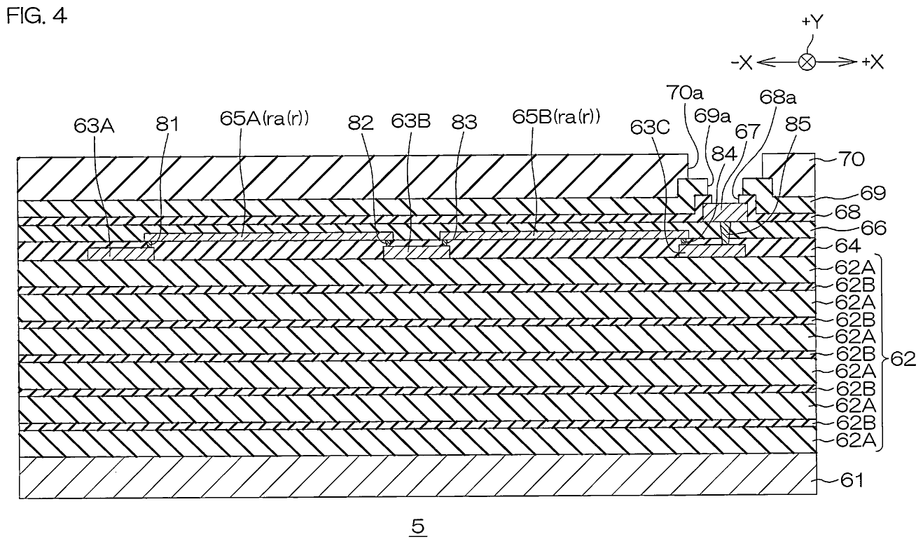

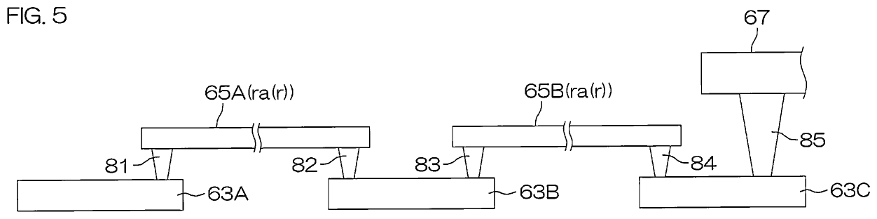

FIG. 4 is a sectional view taken along line IV-IV of FIG. 3. FIG. 5 is a sectional view showing a connection structure of resistors in FIG. 4.

A sectional structure of the first chip 5 shall be described. The first chip 5 includes a substrate 61, an insulating film laminated structure 62 that is formed on the substrate 61, a plurality of lower metals 63A, 63B, and 63C that are formed on the insulating film laminated structure 62, a first insulating layer 64 that is formed on the insulating film laminated structure 62 such as to cover the lower metals 63A, 63B, and 63C, and a plurality of resistors 65A and 65B that are formed on the first insulating layer 64 and constitute resistors r.

Further, the first chip 5 includes a second insulating layer 66 that is formed on the first insulating layer 64 such as to cover the resistors 65A and 65B, a plurality of upper metals 67 that are formed on the second insulating layer 66, and a third insulating layer 68 that is formed on the second insulating layer 66 such as to cover the upper metals 67. Further, the first chip 5 includes a first protective film 69 that is formed on the third insulating layer 68 and a second protective film 70 that is formed on the first protective film 69.

The substrate 61 is constituted, for example, of an Si substrate. The insulating film laminated structure 62 has a structure in which a first insulating film 62A constituted of an SiO₂ film and a second insulating film 62B constituted of an SiN (tensile SiN) film having tensile stress are laminated alternately. The number of laminated layers of the first insulating film 62A and the second insulating film 62B may be any number and may differ from the number of laminated layers shown in FIG. 4. The two types of insulating films 62A and 62B are laminated to control warping of the substrate 61 caused by film-forming of the first insulating film 62A by film-forming of the second insulating film 62B and film-form the insulating film thickly.

A film thickness of the first insulating film 62A is, for example, approximately 2 μm and a film thickness of the second insulating film 62B is, for example, approximately 0.3 μm. A thickness of the insulating film laminated structure 62 is, for example, approximately 10 μm.

The lower metals 63A, 63B, and 63C are disposed to electrically connect the real resistors ra that are adjacent in the Y direction to each other and electrically connect the real resistors ra that are adjacent in the X direction to each other. In the example of FIG. 4, the lower metals 63A, 63B, and 63C include the first lower metal 63A disposed close to a −X side end, the third lower metal 63C disposed close to a +X side end, and the second lower metal 63B disposed between the first lower metal 63A and the third lower metal 63C. The lower metals 63A, 63B, and 63C are constituted, for example, of Al (aluminum).

The first insulating layer 64 is constituted, for example, of an SiO₂ layer. The resistors 65A and 65B include the first resistor 65A disposed such as to extend across the first lower metal 63A and the second lower metal 63B and the second resistor 65B disposed such as to extend across the second lower metal 63B and the third lower metal 63C in plan view. The first resistor 65A constitutes a resistor r of the first column and the second resistor 65B constitutes a resistor r of the second column. The resistors 65A and 65B are constituted, for example of CrSi.

A −X side end portion of a low surface of the first resistor 65A is electrically connected to the first lower metal 63A via a first via 81 that penetrates through the first insulating layer 64. A +X side end portion of the low surface of the first resistor 65A is electrically connected to the second lower metal 63B via a second via 82 that penetrates through the first insulating layer 64.

A −X side end portion of a low surface of the second resistor 65B is electrically connected to the second lower metal 63B via a third via 83 that penetrates through the first insulating layer 64. A +X side end portion of the low surface of the second resistor 65B is electrically connected to the third lower metal 63C via a fourth via 84 that penetrates through the first insulating layer 64.

The second insulating layer 66 is constituted, for example, of an SiO₂ layer. The plurality of upper metals 67 function as pads arranged to connect predetermined real resistors ra to predetermined terminals P3 to P6 or connect two predetermined real resistors ra that are not connected by the lower metals 63A to 63C to each other.

In the example of FIG. 4, an upper metal 67 is disposed such that a portion overlaps with a +X side end portion of the third lower metal 63C in plan view. The upper metal 67 is electrically connected to the third lower metal 63C via a fifth via 85 that penetrates continuously through the second insulating layer 66 and the first insulating layer 64. The upper metal 67 shown in FIG. 4 is connected to the terminal P1 via the wiring 52 (see FIG. 3).

The third insulating layer 68 is constituted, for example, of an SiO₂ layer. A pad opening 68a arranged to expose a portion of a front surface of the upper metal 67 is formed in the third insulating layer 68.

The first protective film 69 is constituted, for example, of an SiN film. An opening 69a that is in communication with the pad opening 68a is formed in the first protective film 69. The second protective film 70 is constituted, for example, of a polyimide film. An opening 70a that is in communication with the openings 69a and 68a is formed in the second protective film 70.

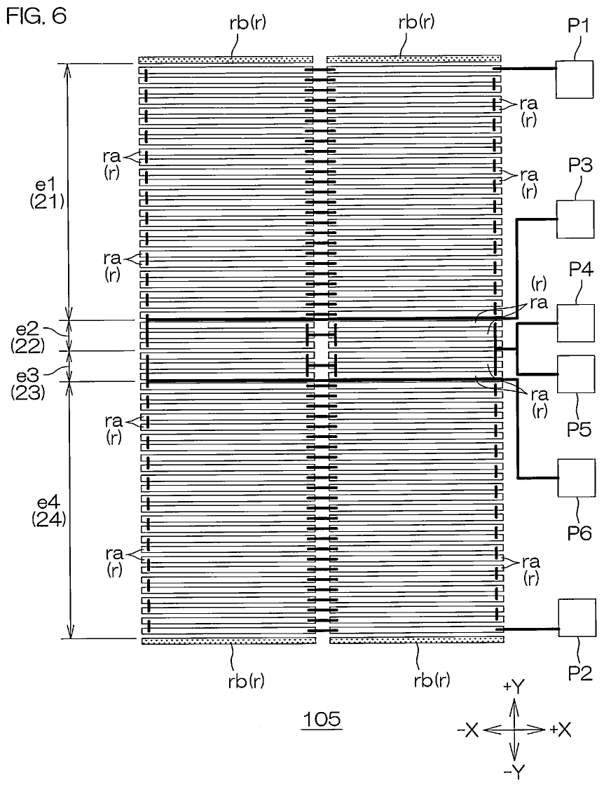

FIG. 6 shows a comparative example 105 of the first chip 5. In FIG. 6, respective portions corresponding to those in FIG. 3 are indicated with the same reference signs attached as in FIG. 3.

A region between the +Y side dummy resistors rb and the −Y side dummy resistors rb is divided into four regions e1 to e4 in the Y direction to form the first to fourth resistor circuits 21 to 24, etc. The regions e1 to e4 shall be referred to respectively as the first region e1, the second region e2, the third region e3, and the fourth region e4 from the +Y direction side.

Sizes of the first region e1 and the fourth region e4 are substantially equal and larger than those of the other regions e2 and e3. The sizes of the second region e2 and the third region e3 are substantially equal. The plurality of resistors r included in each of the first region e1, the second region e2, the third region e3, and the fourth region e4 are real resistors ra.

The first resistor circuit 21 is constituted of a series circuit of all of the real resistors ra inside the first region e1. The second resistor circuit 22 is constituted of a series circuit of a parallel circuit of a plurality of real resistors ra of the first column inside the second region e2 and a parallel circuit of a plurality of real resistors ra of the second column inside the second region e2. The third resistor circuit 23 is constituted of a series circuit of a parallel circuit of a plurality of real resistors ra of the first column inside the third region e3 and a parallel circuit of a plurality of real resistors ra of the second column inside the third region e3. The fourth resistor circuit 24 is constituted of a series circuit of all of the real resistors ra inside the fourth region e4.

That is, in the comparative example 105, a real resistor set that constitutes the second resistor circuit 22 is disposed at the −Y side of a real resistor set that constitutes the first resistor circuit 21. Also, a real resistor set that constitutes the third resistor circuit 23 is disposed at the +Y side of a real resistor set that constitutes the fourth resistor circuit 24.

With the preferred embodiment and the comparative example 105, there is a possibility that resistance characteristics of the resistors r will vary due to process variation when the first chip 5 is manufactured. The process variation tends to occur in a stepwise manner along one direction, for example, the −Y direction or the +Y direction.

With the comparative example 105, since the real resistor set that constitutes the first resistor circuit 21 and the real resistor set that constitutes the second resistor circuit 22 are disposed in parallel in one direction (the Y direction), a difference between a resistance characteristic of the real resistors ra inside the first resistor circuit 21 and a resistance characteristic of the real resistors ra inside the second resistor circuit 22 arises readily due to process variation. Consequently, an error rises readily in the ratio (R2/R1) of the resistance value R2 of the second resistor circuit 22 with respect to the resistance value R1 of the first resistor circuit 21.

Similarly, since the real resistor set that constitutes the fourth resistor circuit 24 and the real resistor set that constitutes the third resistor circuit 23 are disposed in parallel in one direction (the Y direction), a difference between a resistance characteristic of the real resistors ra inside the fourth resistor circuit 24 and a resistance characteristic of the real resistors ra inside the third resistor circuit 23 arises readily due to process variation. Consequently, an error rises readily in the ratio (R3/R4) of the resistance value R3 of the third resistor circuit 23 with respect to the resistance value R4 of the fourth resistor circuit 24.

On the other hand, with the preferred embodiment, if two real resistors ra adjacent in the X direction are deemed to be a real resistor pair, the real resistor set that constitutes the second resistor circuit 22 is disposed between two real resistor pairs adjacent in the Y direction among the real resistor set that constitutes the first resistor circuit 21. Thereby, a difference is made unlikely to arise between an average value of resistance values of the real resistors ra inside the first resistor circuit 21 and an average value of resistance values of the real resistors ra inside the second resistor circuit 22. Consequently, an error is made unlikely to arise in the ratio (R2/R1) of the resistance value R2 of the second resistor circuit 22 with respect to the resistance value R1 of the first resistor circuit 21.

Similarly, with the preferred embodiment, if two real resistors ra adjacent in the X direction are deemed to be a real resistor pair, the real resistor set that constitutes the third resistor circuit 23 is disposed between two real resistor pairs adjacent in the Y direction among the real resistor set that constitutes the fourth resistor circuit 24. Thereby, a difference is made unlikely to arise between an average value of resistance values of the real resistors ra inside the fourth resistor circuit 24 and an average value of resistance values of the real resistors ra inside the third resistor circuit 23. Consequently, an error is made unlikely to arise in the ratio (R3/R4) of the resistance value R3 of the third resistor circuit 23 with respect to the resistance value R4 of the fourth resistor circuit 24.

As mentioned above, when the second resistor circuit 22 is disposed as in the preferred embodiment, a high voltage difference is generated between the second resistor circuit 22 and the real resistors ra adjacent thereto of the first resistor circuit 21. Also, when the third resistor circuit 23 is disposed as in the preferred embodiment, a high voltage difference is generated between the third resistor circuit 23 and the real resistors ra adjacent thereto of the fourth resistor circuit 24. However, in the preferred embodiment, the dummy resistors rb are disposed at the locations at which the high voltage differences are generated and therefore, the electric fields at the locations at which the high voltage differences are generated can be relaxed.

The present disclosure can be implemented in yet other modes. For example, in the preferred embodiment described above, two dummy resistors rb are disposed at the predetermined pitch interval in the Y direction between the second resistor circuit 22 and the real resistors ra adjacent thereto of the first resistor circuit 21 for each of the first column and the second column. However, one dummy resistor rb may be disposed or three or more dummy resistors rb may be disposed at the predetermined pitch interval between the second resistor circuit 22 and the real resistors ra adjacent thereto of the first resistor circuit 21 for each of the first column and the second column. The same also applies to the dummy resistors rb that are disposed between the third resistor circuit 23 and the real resistors ra adjacent thereto of the fourth resistor circuit 24.

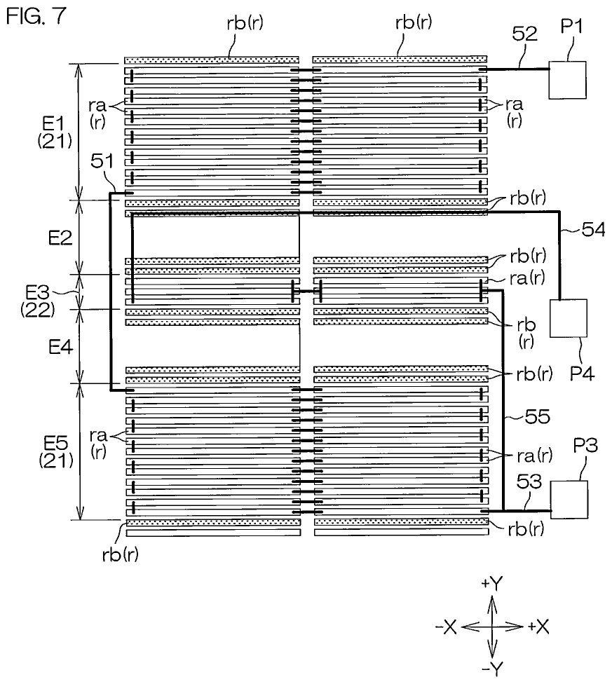

Also, as shown in FIG. 7, a plurality of dummy resistors rb may have a portion thereof disposed at an interval wider than the predetermined pitch interval instead of all being disposed at the predetermined pitch interval between the second resistor circuit 22 and the real resistors ra adjacent thereto of the first resistor circuit 21 for each of the first column and the second column.

Specifically, in each column in the second region E2, four dummy resistors rb are disposed at intervals in the Y direction with the second dummy resistor rb from the +Y side end and the third dummy resistor rb from the +Y side end being disposed at an interval wider than the predetermined pitch interval. Similarly, in each column in the fourth region E4, four dummy resistors rb are disposed at intervals in the Y direction with the second dummy resistor rb from the +Y side end and the third dummy resistor rb from the +Y side end being disposed at an interval wider than the predetermined pitch interval. The same also applies to the dummy resistors rb that are disposed between the third resistor circuit 23 and the real resistors ra adjacent thereto of the fourth resistor circuit 24.

Further, instead of disposing the dummy resistors rb, a space of a width greater than the predetermined pitch interval may simply be formed between the second resistor circuit 22 and the real resistors ra adjacent thereto of the first resistor circuit 21 for each of the first column and the second column. A space greater than the predetermined pitch interval may simply be formed instead of disposing the dummy resistors rb between the third resistor circuit 23 and the real resistors ra adjacent thereto of the fourth resistor circuit 24 as well.

With the preferred embodiment described above, all of the real resistors ra constituting the second resistor circuit 22 are disposed between the two predetermined real resistors ra adjacent in the Y direction in the first resistor circuit 21. However, it suffices for at least a portion of the real resistors ra among the plurality of real resistors ra constituting the second resistor circuit 22 to be disposed between two real resistors ra adjacent in the Y direction in the first resistor circuit 21. Also, a portion of the plurality of real resistors ra constituting the second resistor circuit 22 may be disposed between the two predetermined real resistors ra adjacent in the Y direction in the first resistor circuit 21 and another portion of the plurality of real resistors ra constituting the second resistor circuit 22 may be disposed between another two real resistors ra adjacent in the Y direction in the first resistor circuit 21. The same also applies to the positioning with respect to the fourth resistor circuit 24 of the real resistors ra constituting the third resistor circuit 23.

Also, with the preferred embodiment described above, two columns each constituted of the plurality of resistors r that extend in the X direction and are disposed at intervals in the Y direction are provided at an interval in the X direction in plan view in the first chip 5. However, three or more of such columns may be provided at intervals in the X direction or just one column may be provided instead.

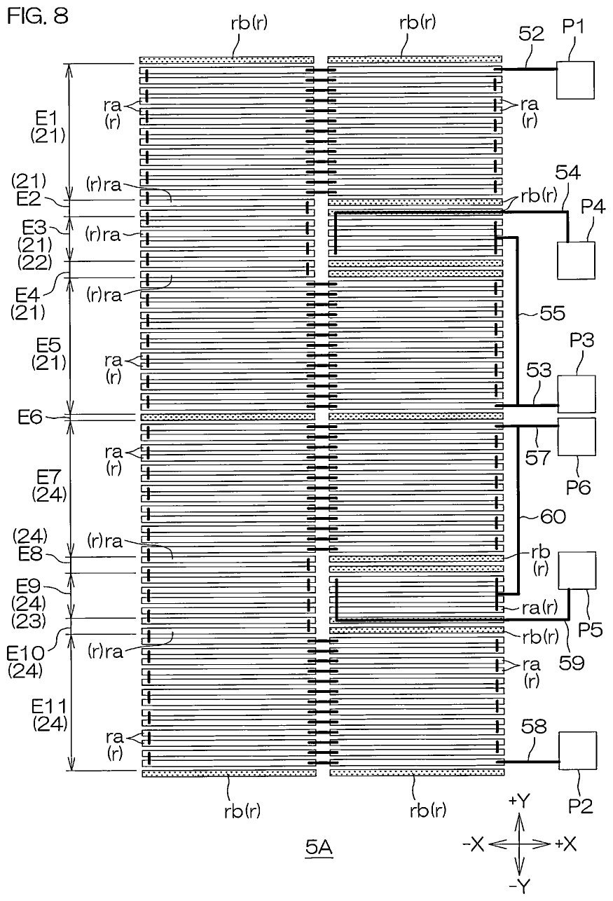

FIG. 8 is an illustrative plan view for describing a modification example of a first chip. In FIG. 8, respective portions corresponding to those in FIG. 3 are indicated with the same reference signs attached as in FIG. 3.

In a first chip 5A of FIG. 8, four real resistors ra are disposed at intervals in the Y direction in each of the first column and the second column inside the third region E3. The four real resistors ra disposed in the second column inside the third region E3 are, as in FIG. 3, real resistors ra that are used as resistors of the second resistor circuit 22. However, unlike in FIG. 3, the four real resistors ra disposed in the first column inside the third region E3 are real resistors ra that are used as resistors of the first resistor circuit 21.

Whereas in the first chip 5 of FIG. 3, two dummy resistors rb are disposed in each of the first column and the second column inside the second region E2, in the first chip 5A of FIG. 8, two real resistors ra are disposed in the first column inside the second region E2.

Similarly, whereas in the first chip 5 of FIG. 3, two dummy resistors rb are disposed in each of the first column and the second column inside the fourth region E4, in the first chip 5A of FIG. 8, two real resistors ra are disposed in the first column inside the fourth region E4.

In the first chip 5A of FIG. 8, the first resistor circuit 21 is constituted of the plurality of real resistors ra inside the first region E1, the two real resistors ra of the first column inside the second region E2, the plurality of real resistors ra of the first column inside the third region E3, the two real resistors ra of the first column inside the fourth region E4, and the plurality of real resistors ra inside the fifth region E5. The first resistor circuit 21 is constituted of a series circuit of all of the real resistors ra included in the first region E1, the first column inside the second region E2, the first column inside the third region E3, the first column inside the fourth region E4, and the fifth region E5.

Specifically, inside the region E1, two real resistors ra that are adjacent in the X direction have the inner end portions thereof electrically connected to each other. In the first column inside the region E1, the −X side end portions of the real resistors ra of odd number rows from the +Y side end are respectively connected to the −X side end portions of the real resistors ra of even number rows that are adjacent to −Y sides thereof. In the second column inside the region E1, the +X side end portions of the real resistors ra of even number rows from the +Y side end are respectively connected to the +X side end portions of the real resistors ra of odd number rows that are adjacent to the −Y sides thereof.

If a region integrating the region E2, the region E3, and the region E4 is deemed to be a first integrated region, in the first column inside the first integrated region, the −X side end portions of the real resistors ra of even number rows from the +Y side end are respectively connected to the −X side end portions of the real resistors ra of odd number rows that are adjacent to the −Y sides thereof. Also, in the first column inside the first integrated region, the +X side end portions of the real resistors ra of odd number rows from the +Y side end are respectively connected to the +X side end portions of the real resistors ra of even number rows that are adjacent to the −Y sides thereof.

Inside the region E5, two real resistors ra that are adjacent in the X direction have the inner end portions thereof electrically connected to each other. In the first column inside the region E5, the −X side end portions of the real resistors ra of even number rows from the +Y side end are respectively connected to the −X side end portions of the real resistors ra of odd number rows that are adjacent to the −Y sides thereof. In the second column inside the region E5, the +X side end portions of the real resistors ra of odd number rows from the +Y side end are respectively connected to the +X side end portions of the real resistors ra of even number rows that are adjacent to the −Y sides thereof.

The −X side end portion of the real resistor ra at the −Y side end of the first column inside the region E1 is connected to the −X side end portion of the real resistor ra at the +Y side end of the first column inside the first integrated region. The −X side end portion of the real resistor ra at the −Y side end of the first column inside the first integrated region is connected to the −X side end portion of the real resistor ra at the +Y side end of the first column inside the region E5. All of the real resistors ra included inside the region E1, in the first column inside the first integrated region, and inside the region E5 are thereby connected in series.

The +X side end portion of the real resistor ra at the +Y side end of the second column inside the region E1 is connected via the wiring 52 to the terminal P1. The +X side end portion of the real resistor ra at the −Y side end of the second column inside the region E5 is connected via the wiring 53 to the terminal P3.

The second resistor circuit 22 is constituted of a parallel circuit of the plurality (four in the example of FIG. 12) of real resistors ra of the second column inside the third region E3.

Specifically, the −X side end portions of the plurality of real resistors ra of the second column inside the third region E3 are electrically connected to each other and the +X side end portions of these real resistors ra are electrically connected to each other. The −X side end portions of the plurality of real resistors ra of the second column inside the third region E3 are connected via the wiring 54 to the terminal P4. The +X side end portions of the plurality of real resistors ra of the second column inside the third region E3 are connected via the wiring 55 to the terminal P3.

Also, in the first chip 5A of FIG. 8, four real resistors ra are disposed at intervals in the Y direction in each of the first column and the second column inside the ninth region E9. The four real resistors ra disposed in the second column inside the ninth region E9 are, as in FIG. 3, real resistors ra that are used as resistors of the third resistor circuit 23. However, unlike in FIG. 3, the four real resistors ra disposed in the first column inside the ninth region E9 are real resistors ra that are used as resistors of the fourth resistor circuit 24.

Whereas in the first chip 5 of FIG. 3, two dummy resistors rb are disposed in each of the first column and the second column inside the eighth region E8, in the first chip 5A of FIG. 8, two real resistors ra are disposed in the first column inside the eighth region E8.

Similarly, whereas in the first chip 5 of FIG. 3, two dummy resistors rb are disposed in each of the first column and the second column inside the tenth region E10, in the first chip 5A of FIG. 8, two real resistors ra are disposed in the first column inside the tenth region E10.

In the first chip 5A of FIG. 8, the fourth resistor circuit 24 is constituted of the plurality of real resistors ra inside the seventh region E7, the two real resistors ra of the first column inside the eighth region E8, the plurality of real resistors ra of the first column inside the ninth region E9, the two real resistors ra of the first column inside the tenth region E10, and the plurality of real resistors ra inside the eleventh region E11. The fourth resistor circuit 24 is constituted of a series circuit of all of the real resistors ra included inside the seventh region E7, the first column inside the eighth region E8, the first column inside the ninth region E9, the first column inside the tenth region E10, and inside the eleventh region E11.

Specifically, inside the region E7, two real resistors ra that are adjacent in the X direction have the inner end portions thereof electrically connected to each other. In the first column inside the region E7, the −X side end portions of the real resistors ra of odd number rows from the +Y side end are respectively connected to the −X side end portions of the real resistors ra of even number rows that are adjacent to −Y sides thereof. In the second column inside the region E7, the +X side end portions of the real resistors ra of even number rows from the +Y side end are respectively connected to the +X side end portions of the real resistors ra of odd number rows that are adjacent to the −Y sides thereof.

If a region integrating the region E8, the region E9, and the region E10 is deemed to be a second integrated region, in the first column inside the second integrated region, the −X side end portions of the real resistors ra of even number rows from the +Y side end are respectively connected to the −X side end portions of the real resistors ra of odd number rows that are adjacent to the −Y sides thereof. Also, in the first column inside the second integrated region, the +X side end portions of the real resistors ra of odd number rows from the +Y side end are respectively connected to the +X side end portions of the real resistors ra of even number rows that are adjacent to the −Y sides thereof.

Inside the region E11, two real resistors ra that are adjacent in the X direction have the inner end portions thereof electrically connected to each other. In the first column inside the region E11, the −X side end portions of the real resistors ra of even number rows from the +Y side end are respectively connected to the −X side end portions of the real resistors ra of odd number rows that are adjacent to the −Y sides thereof. In the second column inside the region E11, the +X side end portions of the real resistors ra of odd number rows from the +Y side end are respectively connected to the +X side end portions of the real resistors ra of even number rows that are adjacent to the −Y sides thereof.

The −X side end portion of the real resistor ra at the −Y side end of the first column inside the region E7 is connected to the −X side end portion of the real resistor ra at the +Y side end of the first column inside the second integrated region. The −X side end portion of the real resistor ra at the −Y side end of the first column inside the second integrated region is connected to the −X side end portion of the real resistor ra at the +Y side end of the first column inside the region E11. All of the real resistors ra included inside the region E7, in the first column inside the second integrated region, and inside the region E11 are thereby connected in series.

The +X side end portion of the real resistor ra at the +Y side end of the second column inside the region E7 is connected via the wiring 57 to the terminal P6. The +X side end portion of the real resistor ra at the −Y side end of the second column inside the region E11 is connected via the wiring 58 to the terminal P2.

The third resistor circuit 23 is constituted of a parallel circuit of the plurality (four in the example of FIG. 12) of real resistors ra of the second column inside the ninth region E9.

Specifically, the −X side end portions of the plurality of real resistors ra of the second column inside the ninth region E9 are electrically connected to each other and the +X side end portions of these real resistors ra are electrically connected to each other. The −X side end portions of the plurality of real resistors ra of the second column inside the ninth region E9 are connected via the wiring 59 to the terminal P5. The +X side end portions of the plurality of real resistors ra of the second column inside the ninth region E9 are connected via the wiring 60 to the terminal P6.

While preferred embodiments of the present disclosure were described in detail above, these are merely specific examples used to clarify the technical contents of the present disclosure and the present disclosure should not be interpreted as being limited to these specific examples and the scope of the present disclosure is limited only by the appended claims.

1. A semiconductor device comprising:
a first resistor circuit that is electrically connected to a positive electrode of a high voltage generating portion; a second resistor circuit that is connected in series to the first resistor circuit; a third resistor circuit that is connected in series to the second resistor circuit; and a fourth resistor circuit that is connected in series to the third resistor circuit and electrically connected to a negative electrode of the high voltage generating portion; and
wherein the first resistor circuit includes a plurality of first resistors that extend in a first direction and are disposed at intervals in a second direction orthogonal to the first direction in plan view,
the second resistor circuit includes one second resistor that extends in the first direction or a plurality of second resistors that extend in the first direction and are disposed at intervals in the second direction,
the third resistor circuit includes one third resistor that extends in the first direction or a plurality of third resistors that extend in the first direction and are disposed at intervals in the second direction,
the fourth resistor circuit includes a plurality of fourth resistors that extend in the first direction and are disposed at intervals in the second direction,
the second resistors include one or a plurality of intermediate second resistors disposed between two first resistors adjacent in the second direction among the plurality of first resistors, and
the third resistors include one or a plurality of intermediate third resistors disposed between two fourth resistors adjacent in the second direction among the plurality of fourth resistors.

2. The semiconductor device according to claim 1, wherein resistance values of the first resistors, the second resistors, the third resistors, and the fourth resistors are equal.

3. The semiconductor device according to claim 1, wherein a ratio of a resistance value of the second resistor circuit with respect to a resistance value of the first resistor circuit is equal to a ratio of a resistance value of the third resistor circuit with respect to a resistance value of the fourth resistor circuit.

4. The semiconductor device according to claim 1, wherein one or a plurality of first dummy resistors are disposed between the two first resistors between which the one or plurality of intermediate second resistors are disposed and the intermediate second resistors and
one or a plurality of second dummy resistors are disposed between the two fourth resistors between which the one or plurality of intermediate third resistors are disposed and the intermediate third resistors.

5. The semiconductor device according to claim 1, wherein resistance values of the first resistors, the second resistors, the third resistors, the fourth resistors, the first dummy resistors, and the second dummy resistors are equal.

6. The semiconductor device according to claim 1, wherein the first resistor circuit includes a predetermined number of two or more of columns each constituted of a plurality of the first resistors that extend in the first direction and are disposed at intervals in the second direction,
the fourth resistor circuit includes a predetermined number of two or more of columns each constituted of a plurality of the fourth resistors that extend in the first direction and are disposed at intervals in the second direction,
the second resistor circuit includes one or a plurality of second resistors disposed in correspondence to each column of the first resistors, and
the third resistor circuit includes one or a plurality of third resistors disposed in correspondence to each column of the fourth resistors.

7. The semiconductor device according to claim 1, wherein all of the first resistors constituting the first resistor circuit are connected in series and
all of the fourth resistors constituting the fourth resistor circuit are connected in series.

8. The semiconductor device according to claim 1, wherein the second resistor circuit includes at least four or more second resistors,
the third resistor circuit includes at least four or more third resistors,
the second resistor circuit includes a plurality of first parallel circuits each constituted of two or more of the second resistors being connected in parallel,
the third resistor circuit includes a plurality of second parallel circuits each constituted of two or more of the third resistors being connected in parallel,
the plurality of first parallel circuits are connected in series, and
the plurality of second parallel circuits are connected in series.

9. The semiconductor device according to claim 1, comprising: a voltage detecting portion arranged to measure a voltage that is in accordance with a voltage between a connection point of the first resistor circuit and the second resistor circuit and a connection point of the third resistor circuit and the fourth resistor circuit is included.
